(19) United States
(12) Patent Application Publication
(10) Pub. No.: US 2023/0113514 A1
(43) Pub. Date: Apr. 13, 2023

(54) METHODS FOR SEAMLESS GAP FILLING USING GRADIENT OXIDATION

(71) Applicant: Applied Materials, Inc., Santa Clara, CA (US)

(72) Inventors: Shih Chung Chen, Cupertino, CA (US); Yongjing Lin, San Jose, CA (US); Chi-Chou Lin, San Jose, CA (US); Zhiyong Wang, Livermore, CA (US); Chih-Hsun Hsu, San Jose, CA (US); Mandyam Sriram, San Jose, CA (US); Tza-Jing Gung, San Jose, CA (US)

(73) Assignee: Applied Materials, Inc., Santa Clara, CA (US)

(21) Appl. No.: 17/541,702

(22) Filed: Dec. 3, 2021

Related U.S. Application Data
(60) Provisional application No. 63/254,015, filed on Oct. 8, 2021.

(51) Int. Cl. H01L 21/768; H01L 21/311; H01L 21/02

(52) U.S. Cl. CPC H01L 21/76837; H01L 21/31144; H01L 21/02244

(57) ABSTRACT

Processing methods described herein comprise forming a metal gate film on a narrow feature and a wide feature and depositing a hard mask on the metal gate film. The hard mask forms on the metal gate film at a top, bottom and sidewalls of the wide feature and on a top of the narrow feature to cover the metal gate film. Some processing methods comprise oxidizing the metal gate film on the narrow feature to convert a portion of the metal gate film to a metal oxide film. Some processing methods comprise etching the metal oxide film from the narrow feature to leave a gradient etch profile. Some processing methods comprise filling the narrow feature and the wide feature with a gap fill material comprising one or more of a metal nitride, titanium nitride (TiN) or titanium oxynitride (TiON), the gap fill material substantially free of seams and voids.

### CROSS-REFERENCE TO RELATED APPLICATIONS

This application claims priority to U.S. Provisional Application No. 63/254,015, filed Oct. 8, 2021, the entire disclosure of which is hereby incorporated by reference herein.

### TECHNICAL FIELD

Embodiments of the disclosure generally relate to methods for gap filling of high aspect ratio structures. In particular, embodiments of the disclosure pertain to methods for seamless gap filling of high aspect ratio structures.

### BACKGROUND

In microelectronics device fabrication there is a need to fill narrow trenches having aspect ratios (AR) greater than 10:1 with no voiding for many applications. One application is for shallow trench isolation (STI). For this application, the film needs to be of high quality throughout the trench (having, for example, a wet etch rate ratio less than two) with very low leakage.

Ultra-high density storage devices can be produced using three-dimensional (3D) stacked memory structures. For example, a 3D NAND stacked memory device can be formed from an array of alternating conductive and dielectric layers. A memory hole is formed through the memory layers, and a NAND string is formed by filling the memory hole with appropriate materials. As the dimensions of the structures decrease and the aspect ratios increase, post curing methods of the as deposited films become difficult.

Metal gate stack filling in the gate trench has become more and more challenging due to device scaling. One aspect of device scaling is seamless gap filling to avoid downstream integration issues in advanced node applications. A challenge in device scaling down involves gap filling processes where both wide and narrow structures are present. The challenge is to create a seamless or void-less gap fill in a narrow feature without impacting total device performance by negatively affecting the wide feature. Without being bound by any particular theory of operation, oxidation in the wide feature is believed to negatively impact the overall device performance.

Accordingly, there is a need in the art for methods of seamless gap filling of high aspect ratio structures.

### SUMMARY

One or more embodiments of the disclosure are directed to a processing method. The processing method comprises depositing a hard mask on a metal gate film formed on a substrate surface having a narrow feature and a wide feature. The narrow feature has an aspect ratio greater than or equal to about 15, and the wide feature has an aspect ratio less than or equal to 3. The hard mask forms on the metal gate film at a top, bottom and sidewalls of the wide feature and on a top of the narrow feature to cover the metal gate film, and substantially no hard mask forms on a bottom or sidewalls of the narrow feature leaving the metal gate film. The processing method further comprises oxidizing the metal gate film in the narrow feature to convert a portion of the metal gate film to a metal oxide film. The metal oxide film forms as a gradient oxide layer with an amount of metal oxide decreasing from the top of the narrow feature. The processing method further comprises etching the metal oxide film from the narrow feature to leave a gradient etch profile.

Another embodiment of the disclosure is directed to a processing method. The processing method comprises performing at least one process cycle, each process cycle comprising: depositing a hard mask on a metal gate film formed on a substrate surface having a narrow feature and a wide feature. The narrow feature has an aspect ratio greater than or equal to about 15, and the wide feature has an aspect ratio less than or equal to 3. The hard mask forms on the metal gate film at a top, bottom and sidewalls of the wide feature and on a top of the narrow feature to cover the metal gate film, and substantially no hard mask forms on a bottom or sidewalls of the narrow feature leaving the metal gate film. Each process cycle further comprises oxidizing the metal gate film in the narrow feature to convert a portion of the metal gate film to a metal oxide film. The metal oxide film forms as a gradient oxide layer with an amount of metal oxide decreasing from the top of the narrow feature. Each process cycle further comprises etching the metal oxide film from the narrow feature to leave a gradient etch profile. The processing method further comprises filling the narrow feature and the wide feature with a gap fill material comprising one or more of a metal nitride, titanium nitride (TiN) and titanium oxynitride (TiON), the gap fill material substantially free of seams and voids.

Further embodiments of the disclosure are directed to a processing method. The processing method comprises: (a) depositing a hard mask comprising carbon on a metal gate film formed on a substrate surface having a narrow feature and a wide feature. The narrow feature has an aspect ratio of 20 and a width in a range of 2 nm to 10 nm, and the wide feature has an aspect ratio of 1.5 and a width in a range of from 50 nm to 300 nm. The hard mask forms on the metal gate film at a top, bottom and sidewalls of the wide feature and on a top of the narrow feature to cover the metal gate film, and substantially no hard mask forms on a bottom or sidewall of the narrow feature leaving the metal gate film. The processing method further comprises (b) oxidizing the metal gate film in the narrow feature to convert a portion of the metal gate film to a metal oxide film. The metal oxide film forms as a gradient oxide layer with an amount of metal oxide decreasing from the top of the narrow feature. The processing method further comprises (c) etching the metal oxide film from the narrow feature to leave a gradient etch profile. The processing method further comprises (d) repeating (a) through (c) less than or equal to 10 times. The processing method further comprises (e) filling the narrow feature and the wide feature with a gap fill material comprising titanium oxynitride (TiON).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates an electronic device with a narrow feature and a wide feature formed in a substrate in accordance with one or more embodiments of the disclosure;

FIG. 2 illustrates the electronic device of FIG. 1 after formation of a metal gate film on the narrow feature and the wide feature;

FIG. 3 illustrates the electronic device of FIG. 2 after formation of a hard mask on the substrate surface at the top of the narrow feature and the top of the wide feature to cover the metal gate film;

FIG. 4 illustrates the electronic device of FIG. 3 after oxidizing a portion of the metal gate film to form a metal oxide film on the narrow feature and on the sidewalls of the wide feature;

FIG. 5 illustrates the electronic device of FIG. 4 after etching the metal oxide film on the narrow feature and the wide feature;

FIG. 6 illustrates the electronic device of one or more embodiments after optionally repeating process cycles of forming the hard mask, oxidizing the metal gate film, and etching the metal oxide film;

FIG. 7 illustrates the electronic device of one or more embodiments after optionally removing the hard mask;

FIG. 8 illustrates the electronic device of one or more embodiments after optionally gap filling the narrow feature and/or the wide feature; and

FIG. 9 illustrates a process flow diagram of a processing method in accordance with one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

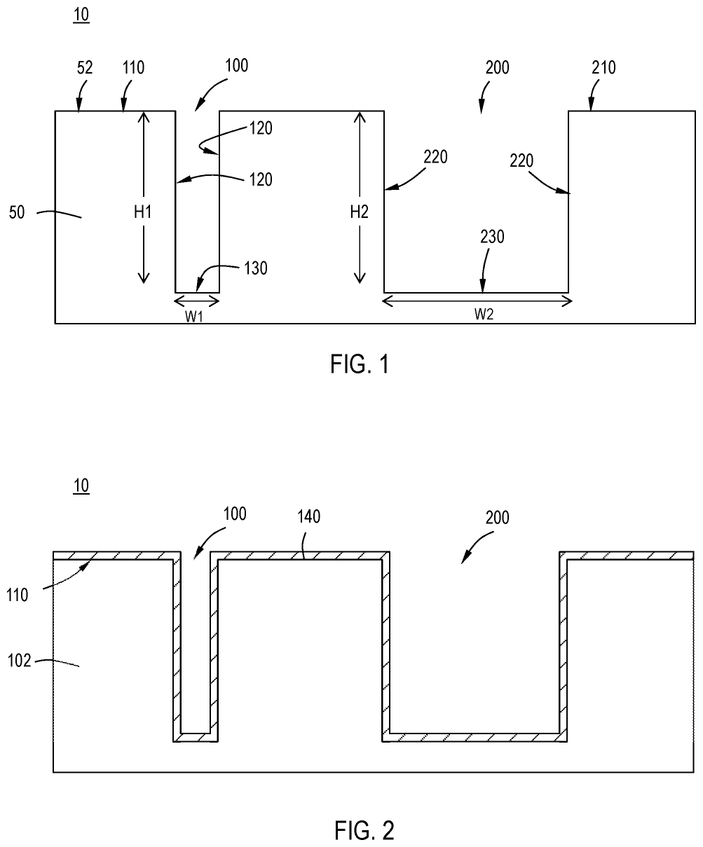

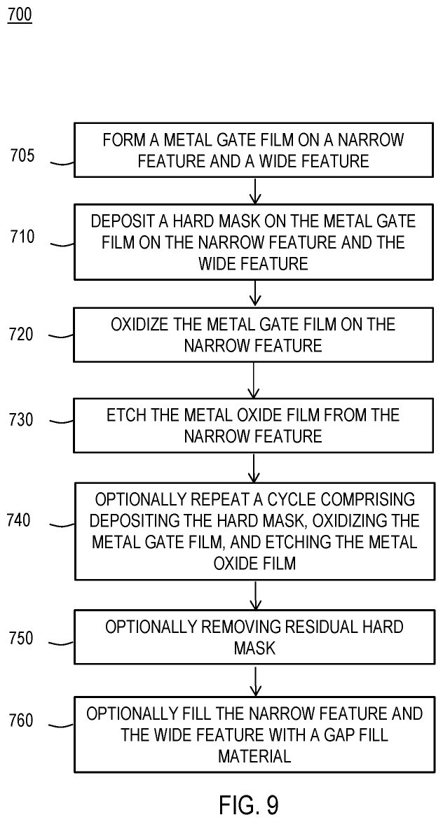

Referring to FIGS. 1-8, an electronic device 10 with a narrow feature 100 and a wide feature 200 formed in a substrate 50 is shown. The narrow feature 100 and wide feature 200 extend a depth into the substrate 50 from the substrate surface 52, as described below. FIG. 9 illustrates a processing method of forming any of the features (e.g., the narrow feature 100 and the wide feature 200) of one or more embodiments shown in FIGS. 1-8. The narrow feature 100 and wide feature 200 illustrated in the drawings has a rectangular cross-section. However, the skilled artisan will recognize that this is merely representative of one possible configuration and that the shape of the narrow feature 100 and the wide feature 200 can be any suitable shape, including, but not limited to elongate trenches and cylindrical vias, with rounded or angular corners. Suitable examples of features include, but are not limited to, trenches which have a top (the substrate surface immediately adjacent the trench), two sidewalls and a bottom, peaks which have a top and two sidewalls, and circular vias with a continuous sidewall. The processes performed and layers/films herein may be described with reference to the narrow feature 100 and/or the wide feature 200, as indicated by the relevant context.

FIG. 1 illustrates the narrow feature 100 having a top 110, sidewalls 120, and a bottom 130. The top 110 of the narrow feature 100 is the region of the substrate surface 52 adjacent to the opening, denoted by the sidewalls 120, of the narrow feature 100. The narrow feature 100 has a height H1, measured as the depth of the narrow feature 100 extending from the substrate surface 52 to the bottom 130. In some embodiments, the height H1 is in the range of 25 nm to 1000 nm, or in the range of 50 nm to 500 nm, or in the range of 75 nm to 250 nm, or in the range of 100 nm to 200 nm. In one or more embodiments, the narrow feature 100 has a width W1 in a range of 2 nm to 10 nm. The width W1 is measured as the average distance between sidewalls 120 measured at equal distances from the bottom 130. In one or more embodiments, the narrow feature 100 has an aspect ratio (measured as the ratio of the height H1 to the width W1) greater than or equal to 15. In one or more embodiments, the aspect ratio of the narrow feature 100 is greater than or equal to 20, greater than or equal to 25, greater than or equal to 30, greater than or equal to 35, greater than or equal to 40, greater than or equal to 45, or greater than or equal to 50.

The wide feature 200 has a top 210, sidewalls 220, and a bottom 230. The top 210 of the wide feature 200 is the region of the substrate surface 52 adjacent to the opening, denoted by the sidewalls 220, of the wide feature 200. The wide feature 200 has a height H2, measured as the depth of the wide feature 200 extending from the substrate surface 52 to the bottom 230. In some embodiments, the height H2 is in the range of 25 nm to 1000 nm, or in the range of 50 nm to 500 nm, or in the range of 75 nm to 250 nm, or in the range of 100 nm to 200 nm. In some embodiments, the height H2 of the wide feature 200 is within ±5%, ±2% or ±1% of the height H1 of the narrow feature 100. The wide feature 200 has a width W2 in a range of from 50 nm to 300 nm. In one or more embodiments, the wide feature 200 has an aspect ratio (measured as the ratio of the height H2 to the width W2) less than or equal to 10, 9, 8, 7, 6, 5, 4, 3, 2 or 1.

FIG. 2 illustrates the electronic device 10 of FIG. 1 after formation of a metal gate film 140 according to operation 705 of method 700. The metal gate film 140 is deposited on the narrow feature 100 and the wide feature 200. In some embodiments, the metal gate film 140 is a conformal film. In some embodiments, the metal gate film 140 is a non-conformal film.

The metal gate film 140 can be any suitable material known to the skilled artisan. In some embodiments, the metal gate film 140 comprises one or more of titanium aluminum carbide (TiAlC), titanium nitride (TiN), tantalum nitride (TaN), tungsten nitride (WN), silicon nitride (SiN), or aluminum nitride (AlN). The metal gate film 140 of some embodiments has a thickness in a range of 1 nm to 30 nm, or in a range of 2 nm to 15 nm.

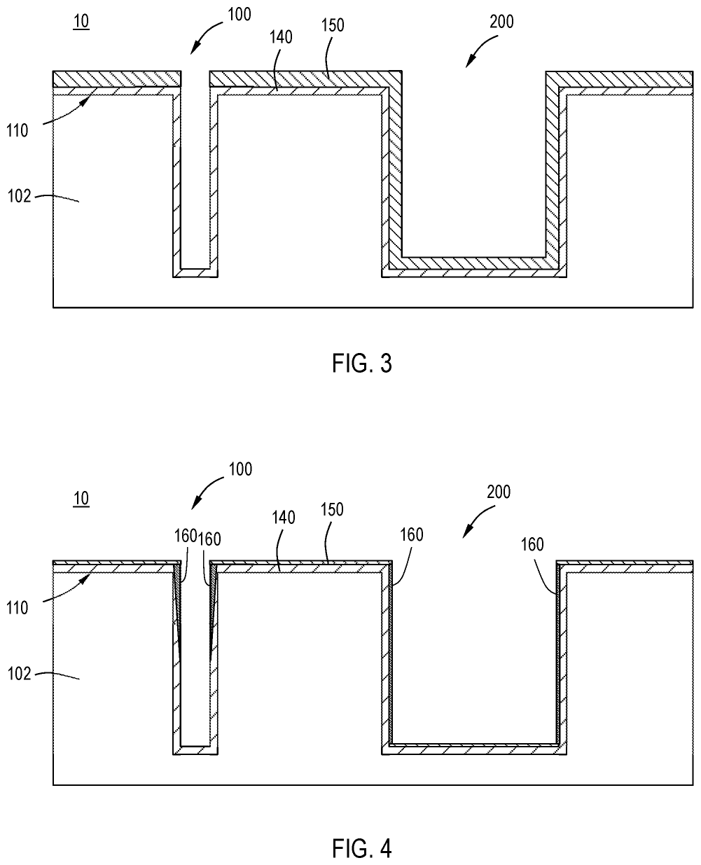

FIG. 3 shows the electronic device 10 of FIG. 2 after formation of a hard mask 150 according to operation 710 of method 700. In some embodiments, the hard mask 150 comprises one or more of carbon (C), titanium nitride (TiN), titanium oxynitride (TiON), silicon dioxide (SiO₂), or silicon nitride (SiN). The hard mask 150 can be deposited by any suitable technique known to the skilled artisan. In one or more embodiments, the hard mask 150 is deposited on the metal gate film 140 by chemical vapor deposition (CVD) or physical vapor deposition (PVD). In some embodiments, the hard mask 150 is deposited by physical vapor deposition (PVD).

In some embodiments, as shown in FIG. 3, the hard mask 150 forms on the substrate surface at the top 110 of the narrow feature 100 and the top 210 of the wide feature to cover the metal gate film 140. In one or more embodiments, substantially no hard mask 150 forms on the metal gate film 140 at the bottom 130 or on the sidewalls 120 of the narrow feature 100, leaving the metal gate film 140 exposed. The skilled artisan will recognize that some hard mask 150 may form on the upper portion of the sidewalls of the narrow feature 100, as shown in FIG. 3. As used in this manner, the term “substantially no hard mask” means that the hard mask 150 on the bottom 130 of the narrow feature 100 and on the bottom two-thirds of the sidewalls 120 of the narrow feature 100 has an average thickness that is less than or equal to about 5%, 2% or 1% of a thickness of the hard mask 150 on the top 110 of the narrow feature 100. In one or more embodiments, the hard mask 150 on the top 110 of the narrow feature 100 has a thickness in a range of from 10 Å to 1000 Å.

As shown in FIG. 3, the hard mask 150 forms on the top 210, bottom 230 and sidewalls 220 of the wide feature 200. In one or more embodiments, the hard mask 150 on the top 210 of the wide feature 200 has a thickness in a range of from 10 Å to 1000 Å. In one or more embodiments, the hard mask 150 on the bottom 230 and the sidewalls 220 of the wide feature 200 has a thickness in a range of from 10 Å to 1000 Å. In some embodiments, the thickness of the hard mask 150 formed on the sidewalls 220 and bottom 230 of the wide feature 200 is smaller than the thickness of the hard mask 150 formed on the top 210 of the wide feature 200.

FIG. 4 illustrates the electronic device 10 of FIG. 3 after oxidizing a portion of the metal gate film 140 according to operation 720 of method 700. Oxidizing a portion of the metal gate film 140 forms a gradient metal oxide film 160 on the narrow feature 100. In one or more embodiments, oxidizing the metal gate film 140, at operation 720, comprises exposing the metal gate film 140 to one or more of an oxidizing plasma or oxygen radicals. The plasma can be any suitable oxidizing plasma known to the skilled artisan. In one or more embodiments, the oxidizing plasma comprises one or more of oxygen (O₂), nitrous oxide (N₂O), water (H₂O), ozone (O₃), an inductively coupled plasma (ICP) thereof, or a capacitively coupled plasma (CCP) thereof. In one or more embodiments, the oxidizing plasma has a high ion concentration. In one or more embodiments, the oxidizing plasma with a high ion concentration has an ion concentration greater than or equal to about 10¹⁰/cm³, or an ion concentration greater than or equal to about 10⁹/cm³, 10¹¹/cm³, 10¹²/cm³, 10¹³/cm³ or 10¹⁴/cm³. The oxidizing plasma used in the treatment can be any suitable plasma (e.g., direct or remote) which is capable of modifying the film properties. In one or more embodiments, about 5% of the metal gate film 140 is converted to the metal oxide film 160. In one or more embodiments, about 10%, about 20%, about 30%, about 40%, about 50%, about 60% or about 70% of the metal gate film 140 is converted to the metal oxide film 160.

In one or more embodiments, the metal oxide film 160 forms as a gradient oxide layer with the thickness of metal oxide film decreasing from the top 110 of the narrow feature 100. In one or more embodiments, the amount of metal oxide at the top 110 of the narrow feature 100 has a thickness in a range of from 500 Å to 1000 Å. In one or more embodiments, the amount of metal oxide at a midpoint between the top 110 and the bottom 130 of the narrow feature 100 has a thickness in a range of from 100 Å to 500 Å. In one or more embodiments, the amount of metal oxide at the bottom 130 of the narrow feature 100 has a thickness in a range of from 10 Å to 100 Å.

In some embodiments, oxidizing the metal gate film 140 results in removal of hard mask 150 on the sidewalls of the wide feature 200 and/or oxidizes a portion of the metal gate film 140 formed on the sidewalls of the wide feature 200. FIG. 4 illustrates a metal oxide film 160 on the sidewalls 220 of the wide feature 200. In one or more embodiments, the metal oxide film 160 on the sidewalls 220 of the wide feature 200 has a thickness in a range of from 10 Å to 1000 Å.

Without being bound by any particular theory of operation, forming the hard mask 150 on the metal gate film 140 on the narrow feature 100, at operation 710, advantageously permits oxidizing the metal gate film 140, at operation 720, without damaging the metal gate film 140. Without being bound by any particular theory of operation, forming the hard mask 150 on the metal gate film 140 on the narrow feature, at operation 710, followed by oxidizing the metal gate film 140, at operation 720, permits formation of the “V” shaped narrow feature 100.

The metal oxide film 160 comprises any suitable oxide known to the skilled artisan. The metal oxide film 160 formed is an oxide of the metal gate film 140 formed in operation 705 of method 700. In some embodiments, the metal oxide film 160 comprises one or more of titanium oxynitride (TiON), tantalum oxynitride (TaON), tungsten oxynitride (WON), silicon oxynitride (SiON), and aluminum oxynitride (AlON).

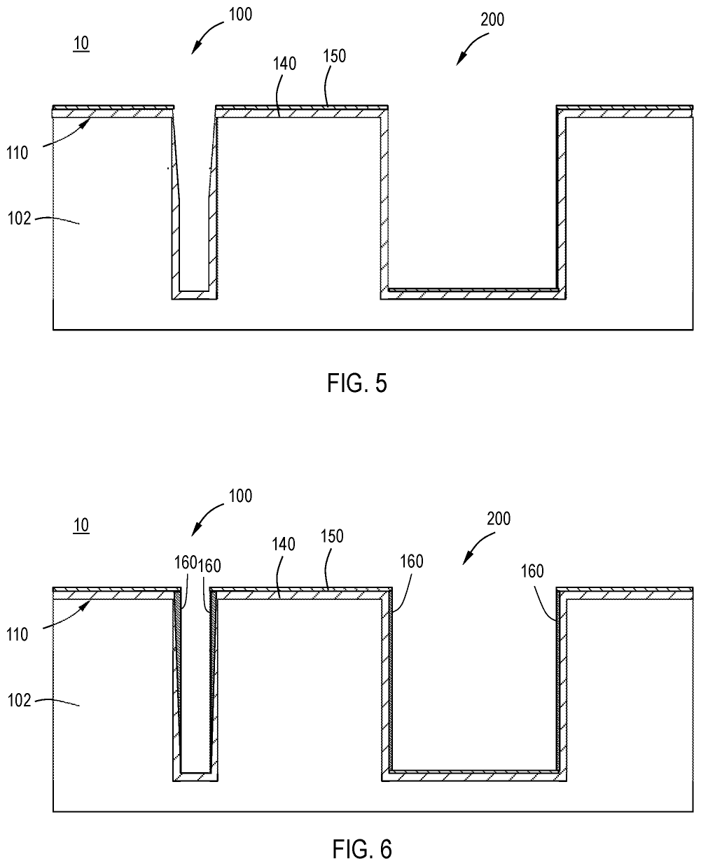

FIG. 5 illustrates the electronic device 10 of FIG. 4 after etching according to operation 730 of method 700. The substrate 50 may be etched, and/or the metal oxide film 160 may be selectively removed, by any process known to one of skill in the art, including, but not limited to, wet etching, plasma-based sputter etching, chemical etching, Siconi® etching, reactive ion etching (RIE), high density plasma (HDP) etching, chemical-mechanical planarization (CMP) and the like. In one or more embodiments, etching the metal oxide film 160 at operation 730 comprises exposing the metal oxide film 160 to one or more of a metal halide, chlorine (Cl₂), nitrogen trifluoride (NF₃), tantalum pentachloride (TaCl₅), tungsten pentachloride (WCl₅), or tungsten dichloride dioxide (WO₂Cl₂). In one or more embodiments, the metal oxide film 160 is entirely removed from the narrow feature 100. In one or more embodiments, substantially none of the metal oxide film 160 remains on the narrow feature 100. As used in this manner, the term “substantially none of the metal oxide film 160” means that less than or equal to about 5%, 2% or 1% of the metal oxide film 160 formed in operation 720 (see FIG. 4) remains after etching.

In one or more embodiments, the metal oxide film 160 is etched from the narrow feature 100 to leave a gradient etch profile. In one or more embodiments, etching according to operation 730 decreases a thickness of the metal oxide film 160 on the narrow feature 100. In some embodiments, after etching according to operation 730, the amount of metal oxide at the top 110 of the narrow feature 100 has a thickness in a range of from 10 Å to 50 Å. In some embodiments, after etching according to operation 730, the amount of metal oxide at a midpoint between the top 110 and the bottom 130 of the narrow feature 100 has a thickness in a range of from 5 Å to 30 Å. In other embodiments, after etching according to operation 730, the amount of metal oxide at the bottom 130 of the narrow feature 100 has a thickness in a range of from 0 Å to 10 Å.

FIG. 5 also illustrates the result of etching the metal oxide film 160 on the wide feature 200 according to operation 730. In one or more embodiments, the metal oxide film 160 is entirely removed from the wide feature 200. In one or more embodiments, substantially none of the metal oxide film 160 remains on the wide feature 200. As used in this manner, the term “substantially none of the metal oxide film 160” means that less than or equal to about 5%, 2% or 1% of the metal oxide film 160 formed in operation 720 (see FIG. 4) remains after etching. In one or more embodiments, etching according to operation 730 decreases a thickness of the metal oxide film 160 on the wide feature 200. In some embodiments, after etching according to operation 730, the metal oxide film 160 on the sidewalls 220 of the wide feature 200 has a thickness in a range of from 5 Å to 30 Å.

The processing method 700 of some embodiments optionally includes, at operation 740, repeating a portion of the processing methods described herein. In one or more embodiments, operations 710, 720 and 730 are repeated to deposit a hard mask on the metal gate film, oxidizing the metal film in a narrow feature to form a metal oxide film, and etching the metal oxide film. In one or more embodiments, the cycle comprises operation 710, operation 720, and operation 730. In one or more embodiments, optional operation 740 includes repeating the cycle less than or equal to 10 times. FIG. 6 illustrates the electronic device 10 after repeated cycles of operations 710, 720 and 730 resulting in a gradient oxidation profile in the narrow feature 100 that extends to, or close to, the bottom of the feature.

In some embodiments, oxidizing and etching results in the formation of a “V” shaped opening to the narrow feature 100 and/or the wide feature 200. Some embodiments of the disclosure advantageously provide one or more of a narrow feature 100 or a wide feature 200 having a “V” shape. Without being bound by any particular theory of operation, the narrow feature 100 and/or the wide feature 200 having the “V” shape advantageously allows for improved gap filling.

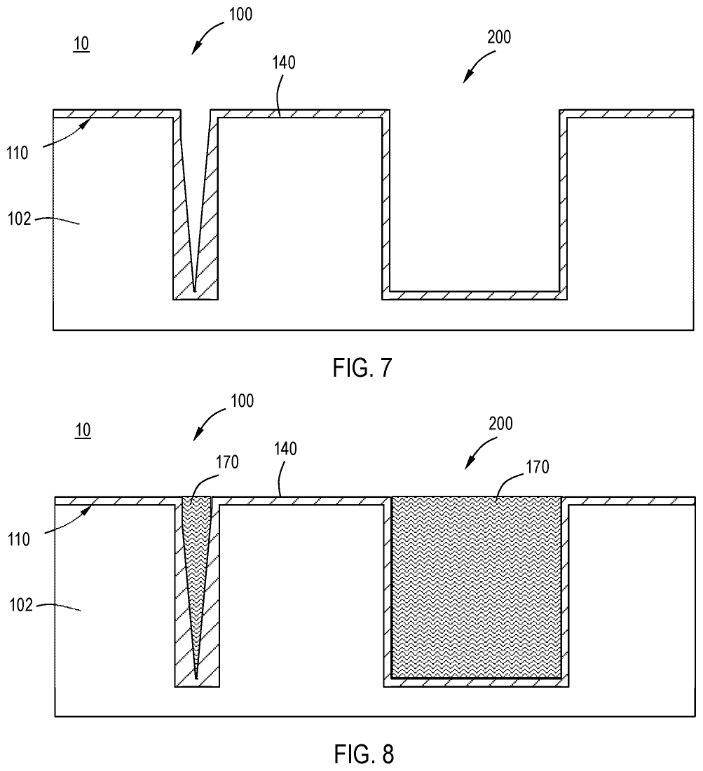

FIG. 7 illustrates the electronic device 10 of FIG. 6 after removing the hard mask 150 in optional operation 750 of method 700. Removal of the hard mask 150 can be done by any suitable technique known to the skilled artisan depending on, for example, the composition of the hard mask. In some embodiments, one or more of the narrow feature 100 or the wide feature 200 have a “V” shape. FIG. 7 illustrates the narrow feature 100 having a “V” shape.

FIG. 8 illustrates the electronic device 10 of FIG. 7 after gap filling according to operation 760 of method 700. In some embodiments, one or more of the narrow feature 100 or the wide feature 200 have a “V” shape. FIG. 8 illustrates the narrow feature 100 having a “V” shape. The narrow feature 100 and the wide feature 200 are filled with a gap fill material 170. The gap fill material 170 can be any suitable material deposited by any suitable technique known to the skilled artisan. In some embodiments, the gap fill material 170 comprises one or more of titanium nitride (TiN) or titanium oxynitride (TiON). In one or more embodiments, the gap fill material 170 comprises substantially no carbon (C). As used in this manner, the term “substantially no carbon” means that the gap fill material 170 comprises less than or equal to about 5%, 2% or 1% carbon (C) on an atomic basis. In one or more embodiments, the gap fill material 170 is substantially free of seams and voids. As used in this manner, the term “substantially free of seams and voids”, and the like, means that less than or equal to 1% of the volume of the stated feature comprises a void or seam.

Some or all of the processes and methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

Embodiments of the disclosure are directed to a non-transitory computer readable medium. In one or more embodiments, the non-transitory computer readable medium includes instructions that, when executed by a controller of a processing chamber, causes the processing chamber to perform the operations of any of the processing methods described herein. In one or more embodiments, the processing chamber performs the operations of processing method 700. In one or more embodiments, the processing chamber performs the operations of: depositing a hard mask on a metal gate film formed on a substrate surface having a narrow feature and a wide feature, the narrow feature having an aspect ratio greater than or equal to about 15, the wide feature having an aspect ratio less than or equal to 3, the hard mask forming on the metal gate film at a top, bottom and sidewalls of the wide feature and on a top of the narrow feature to cover the metal gate film, and substantially no hard mask forms on a bottom or sidewalls of the narrow feature leaving the metal gate film; oxidizing the metal gate film in the narrow feature to convert a portion of the metal gate film to a metal oxide film, the metal oxide film forming as a gradient oxide layer with an amount of metal oxide decreasing from the top of the narrow feature; and etching the metal oxide film from the narrow feature to leave a gradient etch profile.

According to one or more embodiments, the substrate is subjected to processing prior to and/or after forming the layer. This processing can be performed in the same chamber or in one or more separate processing chambers. In one or more embodiments, the deposition/oxidation/etching occurs in the same processing tool.

Several well-known cluster tools which may be adapted for the present disclosure are the Olympia®, the Continuum®, and the Trillium®, all available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), plasma treatment, etch, pre-clean, chemical clean, thermal treatment such as RTP, plasma nitridation, degas, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below”, or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A processing method comprising:
depositing a hard mask on a metal gate film formed on a substrate surface having a narrow feature and a wide feature, the narrow feature having an aspect ratio greater than or equal to about 15, the wide feature having an aspect ratio less than or equal to 3, the hard mask forming on the metal gate film at a top, bottom and sidewalls of the wide feature and on a top of the narrow feature to cover the metal gate film, and substantially no hard mask forms on a bottom or sidewalls of the narrow feature leaving the metal gate film;
oxidizing the metal gate film in the narrow feature to convert a portion of the metal gate film to a metal oxide film, the metal oxide film forming as a gradient oxide layer with an amount of metal oxide decreasing from the top of the narrow feature; and
etching the metal oxide film from the narrow feature to leave a gradient etch profile.

2. The processing method of claim 1, wherein the hard mask comprises one or more of carbon (C), titanium nitride (TiN), titanium oxynitride (TiON), silicon dioxide (SiO₂), and silicon nitride (SiN).

3. The processing method of claim 1, wherein the hard mask on the top of the wide feature and the top of the narrow feature has a thickness in a range of from 10 Å to 1000 Å.

4. The processing method of claim 1, wherein the hard mask on the bottom and the sidewalls of the wide feature has a thickness greater than or equal to 10 Å.

5. The processing method of claim 1, wherein the aspect ratio of the narrow feature is greater than or equal to 20.

6. The processing method of claim 1, wherein the aspect ratio of the wide feature is less than or equal to 2.

7. The processing method of claim 1, wherein the narrow feature has a width in a range of 2 nm to 10 nm and the wide feature has a width in a range of from 50 nm to 300 nm.

8. The processing method of claim 1, wherein oxidizing the metal gate film comprises exposing the metal gate film to one or more of an oxidizing plasma or oxygen radicals.

9. The processing method of claim 8, wherein the oxidizing plasma comprises one or more of oxygen (O₂), nitrous oxide (N₂O), water (H₂O), ozone (O₃), an inductively coupled plasma (ICP) thereof, or a capacitively coupled plasma (CCP) thereof.

10. The processing method of claim 1, wherein the metal oxide film comprises one or more of titanium oxynitride (TiON), tantalum oxynitride (TaON), tungsten oxynitride (WON), silicon oxynitride (SiON), and aluminum oxynitride (AlON).

11. The processing method of claim 1, further comprising repeating a cycle comprising depositing the hard mask, oxidizing the metal gate film and etching the metal oxide film.

12. The processing method of claim 11, wherein the cycle is repeated less than or equal to 10 times.

13. The processing method of claim 1, wherein etching the metal oxide film comprises exposing the metal oxide film to one or more of a metal halide, chlorine (Cl₂), nitrogen trifluoride (NF₃), nitrogen trifluoride (NF₃), tantalum pentachloride (TaCl₅), tungsten pentachloride (WCl₅), or tungsten dichloride dioxide (WO₂Cl₂).

14. The processing method of claim 1, further comprising filling the narrow feature and the wide feature with a gap fill material that is substantially free of seams and voids.

15. The processing method of claim 14, wherein the gap fill material comprises one or more of titanium nitride (TiN) or titanium oxynitride (TiON).

16. The processing method of claim 15, wherein the gap fill material comprises substantially no carbon (C).

17. A processing method comprising:
performing at least one process cycle, each process cycle comprising:
depositing a hard mask on a metal gate film formed on a substrate surface having a narrow feature and a wide feature, the narrow feature having an aspect ratio greater than or equal to about 15, the wide feature having an aspect ratio less than or equal to 3, the hard mask forming on the metal gate film at a top, bottom and sidewalls of the wide feature and on a top of the narrow feature to cover the metal gate film, and substantially no hard mask forms on a bottom or sidewalls of the narrow feature leaving the metal gate film;
oxidizing the metal gate film in the narrow feature to convert a portion of the metal gate film to a metal oxide film, the metal oxide film forming as a gradient oxide layer with an amount of metal oxide decreasing from the top of the narrow feature;
etching the metal oxide film from the narrow feature to leave a gradient etch profile; and
filling the narrow feature and the wide feature with a gap fill material comprising one or more of a metal nitride, titanium nitride (TiN) and titanium oxynitride (TiON), the gap fill material substantially free of seams and voids.

18. The processing method of claim 17, further comprising repeating each process cycle less than or equal to 10 times.

19. The processing method of claim 18, wherein oxidizing the metal gate film comprises exposing the metal gate film to one or more of an oxidizing plasma or oxygen radicals, and the metal oxide film comprises one or more of titanium oxynitride (TiON), tantalum oxynitride (TaON), tungsten oxynitride (WON), silicon oxynitride (SiON), and aluminum oxynitride (AlON).

20. A processing method comprising:
(a) depositing a hard mask comprising carbon on a metal gate film formed on a substrate surface having a narrow feature and a wide feature, the narrow feature having an aspect ratio of 20 and a width in a range of 2 nm to 10 nm, the wide feature having an aspect ratio of 1.5 and a width in a range of from 50 nm to 300 nm, the hard mask forming on the metal gate film at a top, bottom and sidewalls of the wide feature and on a top of the narrow feature to cover the metal gate film, and substantially no hard mask forms on a bottom or sidewall of the narrow feature leaving the metal gate film;
(b) oxidizing the metal gate film in the narrow feature to convert a portion of the metal gate film to a metal oxide film, the metal oxide film forming as a gradient oxide layer with an amount of metal oxide decreasing from the top of the narrow feature;
(c) etching the metal oxide film from the narrow feature to leave a gradient etch profile;
(d) repeating (a) through (c) less than or equal to 10 times; and
(e) filling the narrow feature and the wide feature with a gap fill material comprising titanium oxynitride (TiON).
